(19) United States
(12) Patent Application Publication
(10) Pub. No.: US 2011/0159188 A1
(43) Pub. Date: Jun. 30, 2011

(54) FILM DEPOSITION APPARATUS, FILM DEPOSITION METHOD, AND COMPUTER-READABLE STORAGE MEDIUM

(75) Inventors: Hitoshi Kato, Iwate (JP); Kohichi Orito, Iwate (JP); Hiroyuki Kikuchi, Iwate (JP); Muneyuki Otani, Iwate (JP); Takeshi Kumagai, Iwate (JP); Kensaku Narushima, Yamanashi (JP); Takashi Nishimori, Yamanashi (JP)

(73) Assignee: TOKYO ELECTRON LIMITED, TOKYO (JP)

(21) Appl. No.: 12/972,599

(22) Filed: Dec. 20, 2010

(30) Foreign Application Priority Data
Dec. 25, 2009 (JP) 2009-295351

(51) Int. Cl. C23C 16/34; C23C 16/00; C23C 16/52

(52) U.S. Cl. 427/255.394; 118/730; 118/697

(57) ABSTRACT

A film deposition apparatus rotates a turntable and each gas nozzle relatively to each other at a rotational speed of 100 rpm or higher when depositing a titanium nitride film, to speed up a reaction gas supply cycle or a film deposition cycle of a reaction product. A next film of the reaction product is deposited before the grain size of the reaction product already generated on a substrate surface begins to grow due to crystallization of the already generated reaction product.

### CROSS-REFERENCE TO RELATED APPLICATIONS

This application is based upon and claims the benefit of priority of the prior Japanese Patent Application No.2009-295351, filed on Dec. 25, 2009, the entire contents of which are incorporated herein by reference.

### BACKGROUND. OF THE INVENTION

1. Field of the Invention

The present invention relates to film deposition apparatuses, film deposition methods, and storage media for depositing a titanium nitride film with respect to a substrate in a vacuum environment using reaction gases.

2. Description of the Related Art In a semiconductor device having a multi-level interconnection structure, a contact structure uses a contact hole that is formed in an interlayer insulator to connect an interconnection layer in a lower level to an interconnection layer in an upper level. Aluminum may be used for the metal material embedded within the contact hole. A barrier film is formed on the inner wall surface of the contact hole in order to prevent diffusion of the aluminum into the interlayer insulator. This barrier film is made of a TiN (titanium nitride) film, for example.

From the point of view of coverage, the conventional CVD (Chemical Vapor Deposition) is unsuited for forming such a barrier film on the inner wall surface of the contact hole. Hence, deposition techniques such as ALD (Atomic Layer Deposition), MLD (Molecular Layer Deposition), and SFD (Sequential Flow Deposition) are being studied for possible replacements for the CVD.

When these deposition techniques are used to deposit the TiN film, a TiCl₄ (titanium chloride) gas and a NH₃ (ammonia) gas are alternately supplied onto a semiconductor wafer, in order to successively deposit molecular layers of TiN. According to these deposition techniques, the coverage (or implanting rate) becomes 90% or greater, and the coverage may be greatly improved. However, there is a problem in that the productivity is poor because the deposition rate is low. In addition, if the TiCl₄ gas environment is maintained each time until the TiCl₄ gas adsorption saturates, the surface morphology (or surface state) of the film surface may not be controllable. In other words, if the adsorption time of the reaction gas (that is, supply time of the reaction gas) is set long such that the amount of adsorbed reaction gas on the wafer saturates, in the case of the TiN film, the crystallization of TiN grains generated on the wafer surface progresses while the NH₃ gas is being supplied. As a result, migration of atoms and molecules occur to deteriorate the surface morphology of the TiN film. In the case of the CVD, this progression of the crystallization may not be avoided.

For this reason, if the TiN film is used as a barrier film for ZrO (zirconium oxide), Tip (titanium oxide), and TaO (tantalum oxide) when forming the next-generation capacitor electrode, for example, charges are partially concentrated on the capacitor electrode if the surface morphology of the TiN film is rough.

Furthermore, when the deposition is performed at a low temperature in order to suppress the migration of TiN, for example, the decomposition of the reaction gas may become insufficient. In this case, Cl (chlorine) within the reaction gas may mix into the film, and prevent a designed electrical characteristic to be obtained.

For example, a U.S. Pat. No. 7,153,542, a Japanese Patent No. 3144664, and a U.S. Pat. No. 6,869,641 propose the ALD technique and the like, but the above described problem has not be studied.

### SUMMARY OF THE INVENTION

One object of an embodiment is to provide a film deposition apparatus, a film deposition method, and a computer-readable storage medium that stores a program for carrying out such a method, that enable a titanium nitride film having a smooth surface morphology to be deposited quickly by supplying reaction gases with respect to a substrate within a vacuum chamber.

One aspect of the present invention is to provide a film deposition apparatus comprising a table, provided inside a vacuum chamber, and having a substrate placing region on which a substrate is placed; a first reaction gas supply unit and a second reaction gas supply unit provided at separate locations along a circumferential direction of the vacuum chamber, and configured to supply a first reaction gas including titanium (Ti) and a second reaction gas including nitrogen (N) to the substrate on the table, respectively; a separation region provided between a first process region supplied with the first reaction gas and a second process region supplied with the second reaction gas, and configured to separate the first and second reaction gases; a rotating mechanism configured to rotate one of the table and the first and second reaction gas supply units relative to each other along the circumferential direction of the vacuum chamber so that the substrate passes the first process region and the second process region in this order; a vacuum exhaust unit configured to exhaust the inside of the vacuum chamber to vacuum; and a control unit configured to rotate one of the table and the first and second reaction gas supply units relative to each other via the rotating mechanism at a rotational speed of 100 rpm or higher when depositing a film on the substrate, wherein a titanium nitride film is formed on the substrate by sequentially supplying the first reaction gas and the second reaction gas to a surface of the substrate inside the vacuum chamber.

The film deposition apparatus may further comprise an activation gas injector configured to supply at least one of ammonia (NH₃) gas and hydrogen (H₂) gas with respect to the substrate on the table, wherein the activation gas injector is rotated by the rotating mechanism together with one of the table and the first and second reaction gas supply units in order to rotate relative to each other, and the activation gas injector is arranged to supply the plasma to the substrate between the first process region and the second process region during the relative rotation thereof.

The film deposition apparatus may further comprise a separation gas supply unit configured to supply a separation gas to the separation region. In addition, the film deposition apparatus may have a structure wherein the separation region is formed by the separation gas supply unit and a ceiling surface located on both sides of the separation gas supply unit along the circumferential direction, and a narrow space is formed between the ceiling surface and the table to flow the separation gas from the separation region towards one of the first and second process regions.

The film deposition apparatus may have a structure wherein the first and second reaction gas supply units are respectively provided in a vicinity of the substrate but separated from a ceiling surface in the first and second process regions, and are configured to respectively supply the first and second reaction gases towards the substrate.

One aspect of the present invention is to provide a film deposition method for sequentially supplying a first reaction gas including titanium (Ti) and a second reaction gas including nitrogen (N) to a surface of a substrate inside a vacuum chamber in order to form a titanium nitride film, comprising supplying the first reaction gas and the second reaction gas from a first reaction gas supply unit and a second reaction gas supply unit that are provided at separate locations along a circumferential direction of the vacuum chamber, with respect to a surface of a table that includes a substrate placing region in which the substrate is placed; separating the first and second reaction gases in a separation region provided between a first process region supplied with the first reaction gas and a second process region supplied with the second reaction gas; rotating one of the table and the first and second reaction gas supply units relative to each other along the circumferential direction of the vacuum chamber at a rotational speed of 100 rpm or higher so that the substrate passes the first process region and the second process region in this order; and exhausting the inside of the vacuum chamber to vacuum.

The film deposition method may further comprise supplying at least one of ammonia (NH₃) gas and hydrogen (H₂) gas with respect to the substrate on the table from an activation gas injector, wherein the rotating rotates the activation gas injector together with one of the table and the first and second reaction gas supply units in order to rotate relative to each other, so that the activation gas injector supplies the plasma to the substrate between the first process region and the second process region during the relative rotation thereof.

The film deposition method may supply, by the separating, a separation gas to the separation region from a separation gas supply unit. In addition, the film deposition method may supply the separation gas from the separation gas supply unit to a narrow space formed between the table and a ceiling surface located on both sides of the separation gas supply unit along the circumferential direction so that the separation gas flows from the separation region towards one of the first and second process regions.

The film deposition method may supply, by the supplying, the first and second reaction gases towards the substrate from the first and second reaction gas supply units that are respectively provided in a vicinity of the substrate but separated from a ceiling surface in the first and second process regions.

One aspect of the present invention is to provide a tangible computer-readable storage medium which stores a program which, when executed by a computer, causes the computer to perform a process of a film deposition apparatus that sequentially supplies a first reaction gas including titanium (Ti) and a second reaction gas including nitrogen (N) to a surface of a substrate inside a vacuum chamber in order to form a titanium nitride film, said process comprising a supplying procedure causing the computer to supply the first reaction gas and the second reaction gas from a first reaction gas supply unit and a second reaction gas supply unit that are provided at separate locations along a circumferential direction of the vacuum chamber, with respect to a surface of a table that includes a substrate placing region in which the substrate is placed; a separating procedure causing the computer to separate the first and second reaction gases in a separation region provided between a first process region supplied with the first reaction gas and a second process region supplied with the second reaction gas; a rotating procedure causing the computer to rotate one of the table and the first and second reaction gas supply units relative to each other along the circumferential direction of the vacuum chamber at a rotational speed of 100 rpm or higher so that the substrate passes the first process region and the second process region in this order; and an exhausting procedure causing the computer to exhaust the inside of the vacuum chamber to vacuum.

Other objects and further features of the present invention will be apparent from the following detailed description when read in conjunction with the accompanying drawings.

### BRIEF DESCRIPTION OF THE DRAWINGS

FIG. 1 is a view in vertical cross section illustrating an example of a film deposition apparatus in a first embodiment of the present invention;

FIG. 2 is a perspective view illustrating an example of an internal structure of the film deposition apparatus in the first embodiment;

FIG. 3 is a plan view illustrating the film deposition apparatus in the first embodiment;

FIGS. 4A and 4B are views in vertical cross section illustrating an example of a process region and a separation region of the film deposition apparatus;

FIGS. 5A and 5B are views in vertical cross section illustrating the example of the process region and the separation region of the film deposition apparatus in more detail;

FIG. 6 is a view in vertical cross section illustrating a part of the film deposition apparatus;

FIGS. 7A through 7D are schematic diagrams illustrating an example of a process of depositing a TiN film in the film deposition apparatus;

FIG. 8 is a diagram illustrating an example of gas flow within a vacuum chamber of the film deposition apparatus;

FIGS. 9A through 9D are schematic diagrams illustrating an example of a process of depositing a TiN film using the conventional ALD;

FIG. 10 is a plan view illustrating an example of the film deposition apparatus in a second embodiment of the present invention;

FIG. 11 is a disassembled perspective view illustrating a part of the film deposition apparatus of the second embodiment;

FIG. 12 is an enlarged cross sectional view illustrating the film deposition apparatus of the second embodiment;

FIGS. 13A through 13D are schematic diagrams illustrating an example of a process performed in the film deposition apparatus of the second embodiment;

FIGS. 14A through 14C are diagrams illustrating experimental results obtained in an example embodiment of the present invention; and

FIG. 15 is a diagram illustrating experimental results obtained in an example embodiment of the present invention.

### DESCRIPTION OF THE PREFERRED EMBODIMENTS

Non-limiting, exemplary embodiments of the present invention will now be described with reference to the accompanying drawings. In the drawings, the same or corresponding reference marks are given to the same or corresponding members or components. It is noted that the drawings are illustrative of the invention, and there is no intention to indicate scale or relative proportions among the members or components, alone or therebetween. Therefore, the specific thickness or size should be determined by a person having ordinary skill in the art in view of the following non-limiting embodiments.

### First Embodiment

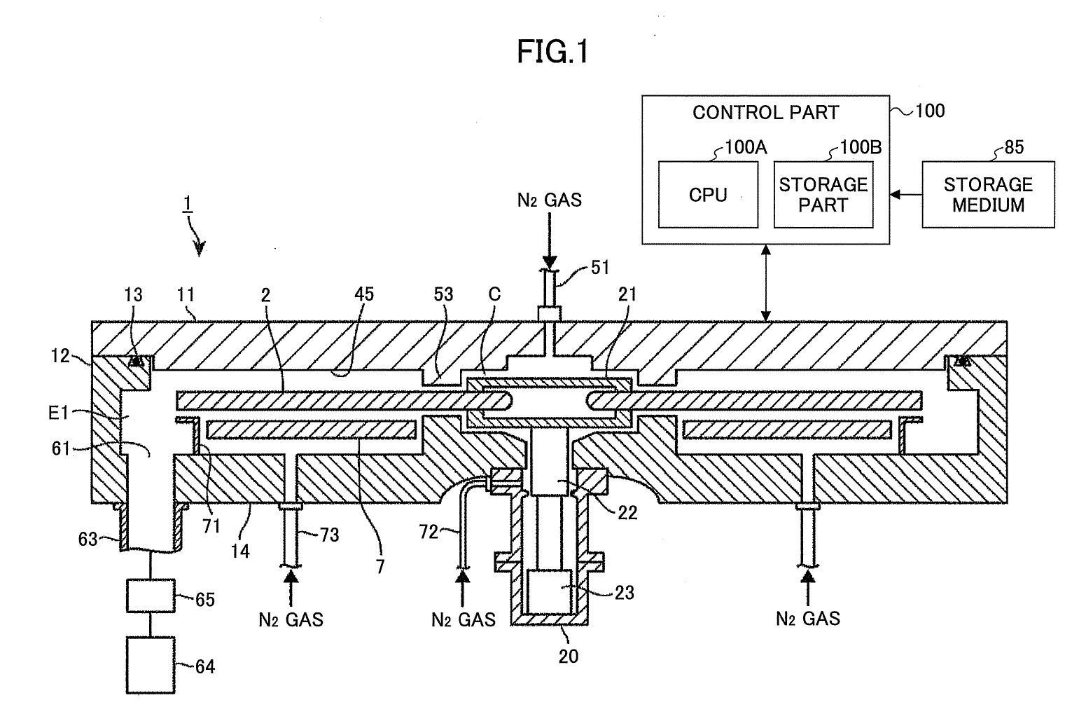

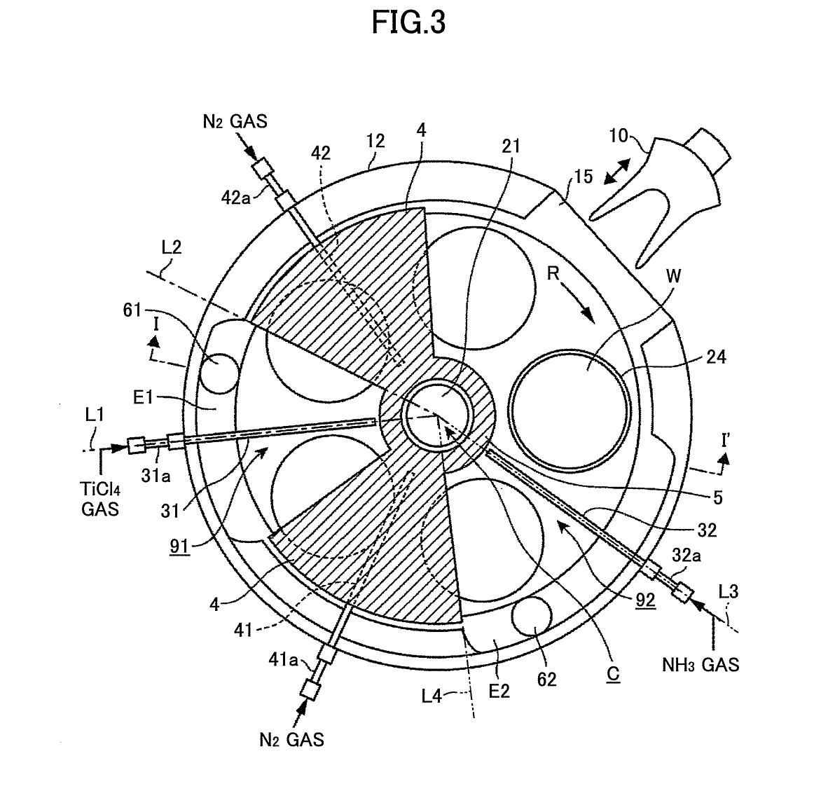

An example of a film deposition apparatus in a first embodiment of the present invention includes a vacuum chamber 1 having a flat cylinder shape that is approximately circular shape in a plan view, and a rotary turntable 2 having a center of rotation (hereinafter referred to as a rotation center) at a central portion within the vacuum chamber 1, as illustrated in FIG. 1 (that is, a vertical cross section along a line I-I′ in FIG. 3) through FIG. 3. A top plate 11 of the vacuum chamber 1 may be attached to and detached from a main chamber body 12 of the vacuum chamber 1. A suitable sealing member, such as an O-ring 13, is provided in a ring shape on a top surface at a peripheral edge portion of the main chamber body 12. The top plate 11 is pushed against the main chamber body 12 via the O-ring 13 due to a decompression state within the vacuum chamber 1, and maintains an airtight state. When removing the top plate 11 from the chamber body 13, the top plate 11 is lifted upwards by a driving mechanism (not illustrated).

A center portion of the turntable 2 is fixed to a cylindrical core part 21, and the core part 21 is fixed to an upper end of a rotary shaft 22 that extends in a vertical direction. The rotary shaft 22 penetrates a bottom surface portion 14 of the vacuum chamber 1, and a lower end of the rotary shaft 22 is mounted on a driving part 23 that forms a rotating mechanism for rotating the rotary shaft 22 clockwise in this example about a vertical axis. As will be described later, the turntable 2 may be rotated by the driving part 23 to rotate about the vertical axis that extends in a vertical direction, at a rotational speed of 100 rpm to 240 rpm, for example, when depositing a thin film by film deposition. The rotary shaft 22 and the driving part 23 are accommodated within a case body 20 that is open at an upper end thereof and has a cylinder shape. A flange portion provided on a top surface of the case body 20 is fixed to a bottom surface of the bottom surface portion 14 of the vacuum chamber 1 in an airtight manner, in order to maintain an airtight state between an inner environment and an outer environment of the case body 20.

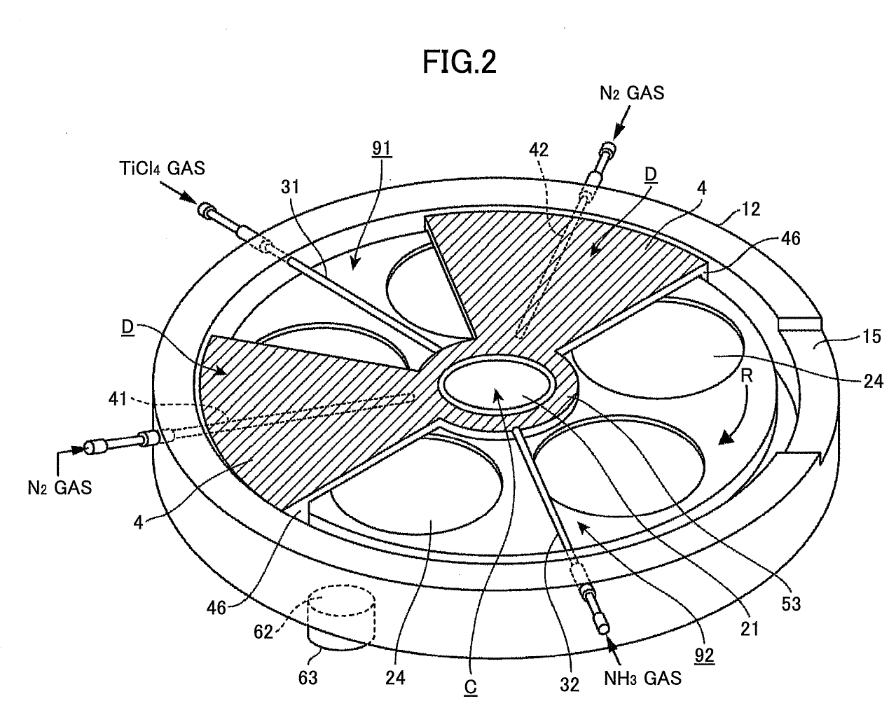

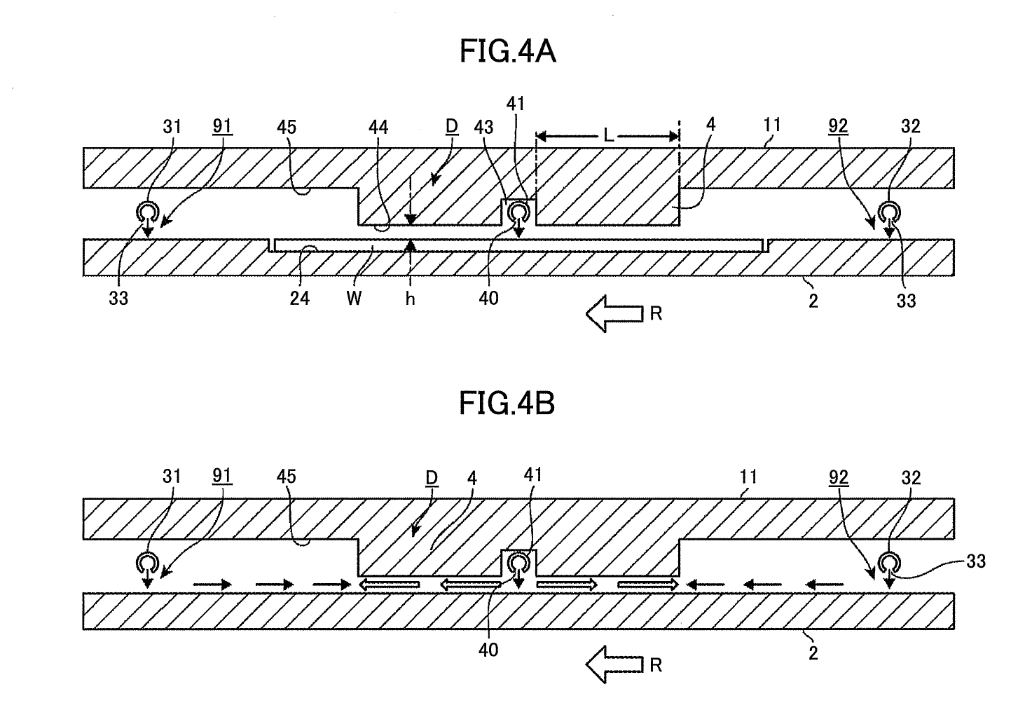

As illustrated in FIGS. 2 and 3, a plurality of recesses 24, each of which is configured to receive a wafer W as the substrate, are formed in an upper surface portion of the turntable 2 along a rotating direction (circumferential direction) R. In this example, the recesses 24 have a circular shape, and five recesses 24 are provided. For the sake of convenience the wafer W is only illustrated within one of the recesses 24 in FIG. 3. FIGS. 4A and 4B are developments obtained by cutting the turntable 2 along a concentric circle and laterally developing the cut portion. As illustrated in FIG. 4A, the recess 24 has a diameter that is slightly larger than the diameter of the wafer W, and has a depth that is approximately the same as the thickness of the wafer. For example, the diameter of the recess 24 is 4 mm larger than that of the wafer W. FIG. 4B illustrates the flow of gas in FIG. 4A by arrows. Accordingly, when the wafer W is placed into the recess 24, a top surface of the wafer W is aligned to the surface of the turntable 2 not placed with the wafer W, that is, the surface of the turntable 2 where the recess 24 is not provided. For example, three elevation pins (not illustrated) penetrate penetration holes (not illustrated) in a bottom surface of the recess 24. The elevation pins support a bottom surface of the wafer W and is configured to raise or lower the wafer W relative to the recess 24.

The recess 24 is configured to position the wafer W, and to prevent the wafer W from falling off the turntable 2 due to centrifugal force when the turntable 2 rotates. The recess 24 may form a substrate placing region.

As illustrated in FIGS. 2 and 3, a first reaction gas nozzle 31, a second reaction gas nozzle 32, and two separation gas nozzles 41 and 42 are provided at positions to oppose the recesses 24 of the turntable 2 in order to supply the gases. The first and second reaction gas nozzles 31 and 32 and the separation gas nozzles 41 and 42 respectively extend in a radial direction from a center portion of the turntable, and are arranged along the peripheral edge of the vacuum chamber 1 at certain intervals in the rotating direction R. In this example, the second reaction gas nozzle 32, the separation gas nozzle 41, the first reaction gas nozzle 31, and the separation gas nozzle 42 are arranged clockwise in this order when viewed from a transport port 15 which will be described later. The first and second reaction gas nozzles 31 and 32 and the separation gas nozzles 41 and 42 are mounted on a sidewall of the vacuum chamber 1, for example, and gas inlet ports 31a, 32a, 41a, and 42a at base ends of the gas nozzles 31, 32, 41, and 42 penetrate the sidewall of the vacuum chamber 1.

The gas nozzles 31, 32, 41, and 42 are introduced into the vacuum chamber 1 from the sidewall of the vacuum chamber 1.

The first reaction gas nozzle 31 is connected to a gas supplying source (not illustrated) for supplying a first reaction gas (or process gas) including Ti (titanium), such as TiCl₄ (titanium chloride), via a flow adjusting valve (not illustrated) or the like. The second reaction gas nozzle 32 is connected to a gas supplying source (not illustrated) for supplying a second reaction gas (or process gas) including N (nitrogen), such as NH₃ (ammonia), via a flow adjusting valve (not illustrated) or the like. Further, each of the two separation gas nozzles 41 and 42 is connected to a gas supplying source for supplying a separation gas (or inert gas), such as N₂ (nitrogen) gas, via a flow adjusting valve (not illustrated) or the like.

Each of the first and second reaction gas nozzles 31 and 32 has a plurality of ejection holes 33, forming process gas supply holes, to eject the corresponding reaction gas downwards in FIG. 4A. For example, the ejection holes 33 have a diameter of 0.3 mm and are arranged at intervals of 2.5 mm along the longitudinal direction of each of the first and second reaction gas nozzles 31 and 32. On the other hand, each of the separation gas nozzles 41 and 42 has a plurality of ejection holes 40, forming process gas supply holes, to eject the separation gas downwards in FIG. 4A. For example, the ejection holes 40 have a diameter of 0.5 mm and are arranged at intervals of 10 mm along the longitudinal direction of each of the separation gas nozzles 41 and 42. The first reaction gas nozzle 31 forms a first reaction gas supply means (or first reaction gas supply unit), and the second reaction gas nozzle 32 forms a second reaction gas supply means (or second reaction gas supply unit). Each of the separation gas nozzles 41 and 42 forms a separation gas supply means (or separation gas supply unit). A first process region 91 in which the TiCl₄ gas is adsorbed on the wafer W and a second process region 92 in which the NH₃ gas is adsorbed on the wafer W are respectively provided under the first and second reaction gas nozzles 31 and 32.

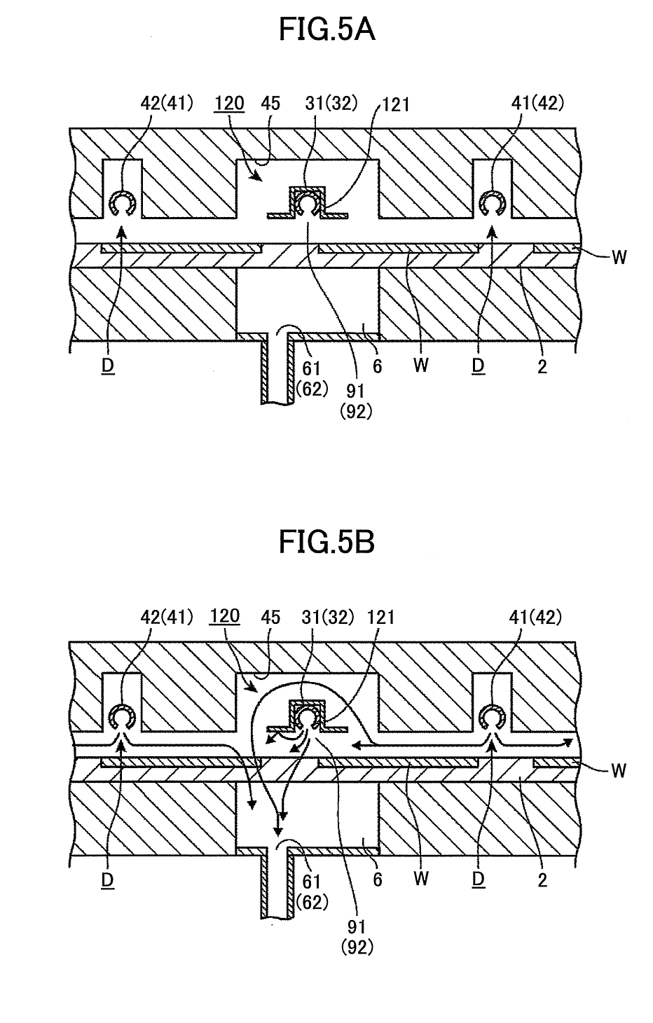

Although the illustration is omitted in FIGS. 1 through 3, 4A and 4B, the first and second reaction gas nozzles 31 and 32 are provided in a vicinity of the wafer W at positions separated from a ceiling surface 45 in the respective first and second process regions 91 and 92, as illustrated in FIG. 5A. In addition, a nozzle cover 120, having an open lower end, is provided to cover each of the first and second reaction gas nozzles 31 and 32 from above, by extending along the longitudinal direction of each of the first and second reaction gas nozzles 31 and 32. Lower ends of the nozzle cover 120 extend horizontally on both sides thereof along the rotating direction R of the turntable 2, and forms a flange-shaped flow regulatory plate (or diffuser) 121. The flow regulatory plate 121 is provided to suppress the separation gas from flowing into the process regions 91 and 92 and to suppress the reaction gas from flowing upwards towards the first and second reaction gas nozzles 31 and 32. The flow regulatory plate 121 has a shape such that a width thereof along the rotating direction R increases from the center towards the outer periphery of the turntable 2. For this reason, as illustrated in FIG. 5B by the arrows indicating the flow of gas, the separation gases flowing from the upstream sides of the first and second reaction gas nozzles 31 and 32 towards the process regions 91 and 92, respectively, pass a region above the nozzle cover 120 and are exhausted via first and second exhaust ports 61 and 62. Hence, the concentration of the reaction gas may be maintained high in each of the process regions 91 and 92. FIGS. 5A and 5B are developments obtained by cutting the turntable 2 along a circumferential direction and laterally developing the cut portion. Thus, although the first and second exhaust ports 61 and 62 of the film deposition apparatus are provided in regions on the outer side relative to the process regions 91 and 92 and a separation region D, FIGS. 5A and 5B for the sake of convenience illustrate the first and second exhaust ports 61 and 62 on the same plane as the process regions 91 and 92 and the separation region D, in order to illustrate the flow of each gas. Of course, the flow regulatory plate 121 may be formed on both sides of the nozzle cover 120 along the rotating direction R of the turntable 2 as illustrated in FIGS. 5A and 5B or, may be formed only on one side of the nozzle cover 120 on the upstream or downstream side along the rotating direction R.

The separation gas nozzles 41 and 42 are provided to form the separation region D in order to separate the first process region 91 from the second process region 92. In the separation region D, the top plate 11 of the vacuum chamber 1 includes a downwardly projecting part 4. As illustrated in FIGS. 2, 3, 4A, and 4B, the projecting part 4 has a fan-shape in the plan view, segmenting a circular region that extends along the inner peripheral surface of the vacuum chamber 1 in the circumferential direction of this circular region. Each of the separation gas nozzles 41 and 42 is accommodated within a groove 43 that is provided in a central portion of the projecting part 4 along the circumferential direction of the circular region and extends in a radial direction of the circular region. In other words, distances from a center axis of the separation gas nozzle 41 (or 42) to both edges of the fan-shaped projecting part 4 along the circumferential direction of the circular region (that is, edges of the fan-shaped projecting part 4 on the upstream side and the downstream side along the rotating direction R of the turntable 2) are set to be the same.

Although the groove 43 equally segments the projecting part 4 into two regions in this example, the groove 43 may be located at a position such that a region on the upstream side of the groove 43 along the rotating direction R of the turntable 2 is larger than a region on the downstream side, for example.

Accordingly, a flat and low ceiling surface (or first ceiling surface) 44 formed by the lower surface of the projecting part 4 is provided on both sides of each of the separation gas nozzles 41 and 42 along the rotating direction R. In addition, a ceiling surface (or second ceiling surface) 45 that is higher than the ceiling surface 44 is formed on both sides of the ceiling surface 44 along the rotating direction R. The projecting part 44 has a function of forming a narrow space between the top plate 11 and the turntable 2, in order to prevent the first and second reaction gases from entering the space between the top plate 11 and the turntable 2 and to prevent the mixing of the first and second reaction gases.

In other words, in the case of the separation gas nozzle 41, for example, the projecting part 2 prevents the NH₃ gas from entering the space between the top plate 11 and the turntable 2 from the upstream side along the rotating direction R of the turntable 2, and to prevent the TiCl₄ gas from entering the space between the top plate 11 and the turntable 2 from the downstream side along the rotating direction R.

In this example, the wafer W, that is used as the substrate to be subjected to the process, has a diameter of 300 mm. In this case, a length of the projecting part 4 in the circumferential direction (a length of an arc of a circle concentric to the turntable 2) is, for example, 146 mm at a portion (that is, a boundary portion between the projecting part 4 and a projecting part 5 which will be described later) separated from the rotation center by 140 mm, and, for example, 502 mm at an outermost portion of the substrate placing region (that is, the recess 24) of the wafer W. As illustrated in FIG. 4A, at the outermost portion, a length L of the projecting part 4 in the circumferential direction is 246 mm, for example, on both sides of the separation gas nozzle 41 (or 42).

As illustrated in FIG. 4A, a height h from the surface of the turntable 2 to the lower surface of the projecting part 4, that is, the ceiling surface 44, is set to 0.5 mm to 4 mm, for example. For this reason, in order to secure the separating function of the separation region 0, the size of the projecting part 4 and the height h from the surface of the turntable 2 to the lower surface of the projecting part 4 (that is, the first ceiling surface 44) may be set based on results of experiments (hereinafter referred to as experimental results) depending on the using range of the rotational speed of the turntable 2 or the like. The separation gas is not limited to the nitrogen (N₂) gas, and other inert gases, such as argon (Ar) gas, may be used for the separation gas.

The projecting part 5 is provided on the lower surface of the top plate 11 along the outer periphery of the core part 21 so as to oppose a portion of the turntable 2 more on the outer periphery than the core part 21. The projecting part 5 is formed continuously to the projecting part 4 on the side closer to the rotation center of the turntable 2, and the lower surface of the projecting part 5 has the same height as the lower surface of the projecting part 4 (that is, the ceiling surface 44). FIGS. 2 and 3 illustrate a state where the top plate 11 is cut horizontally at a height position that is lower than the ceiling surface 45 but is higher than the separation gas nozzles 41 and 42. Of course, the projecting parts 4 and 5 do not necessarily have to be formed integrally, and the projecting parts 4 and 5 may be formed by separate parts.

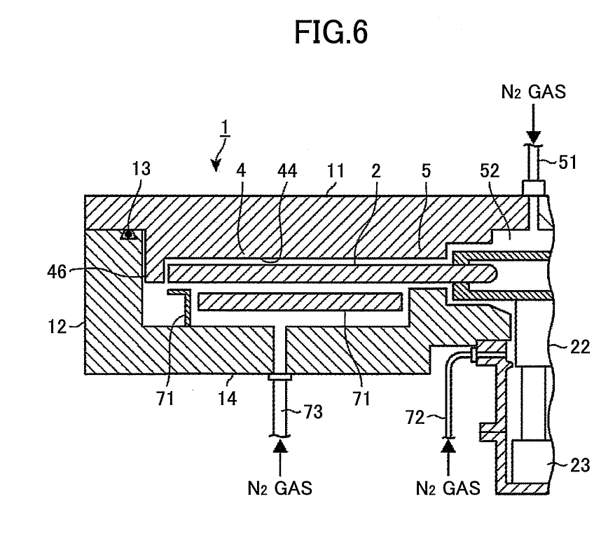

The lower surface of the top plate 11 of the vacuum chamber 1, that is, the ceiling surface viewed from the substrate placing region (that is, recess 24) of the turntable 2, includes the first ceiling surface 44 and the second ceiling surface 45 higher than the first ceiling surface 44 that are arranged in the circumferential direction. FIG. 1 illustrates the vertical cross section of the region provided with the higher ceiling surface 45, while FIG. 6 illustrates the vertical cross section of the region provided with the lower ceiling surface 44. The peripheral edge portion of the fan-shaped projecting part 4 (that is, the portion on the outer edge side of the vacuum chamber 1) is bent in an L-shape to form a bent part 46 in order to oppose the outer end surface of the turntable 2, as illustrated in FIGS. 2 and 6. Because the fan-shaped projecting part 4 is provided on the top plate 11 and may be detachable from the main chamber body 12, a slight gap is formed between the outer peripheral surface of the bent part 46 and the main chamber body 12. The bent part 46 is provided to prevent the reaction gas from entering from both sides, and to prevent the mixing of the two reaction gases, similarly to the projecting part 4. The gap between the inner peripheral surface of the bent part 46 and the outer end surface of the turntable 2, and the gap between the outer peripheral surface of the bent part 46 and the main chamber body 12 are set to a value similar to the height h from the surface of the turntable 2 to the ceiling surface 44. In this example, the inner peripheral surface of the bent part 46 may be regarded as forming the inner peripheral surface of the vacuum chamber 1 when viewed from the surface region of the turntable 2.

The inner wall of the main chamber body 12 is formed by a vertical (or perpendicular) surface adjacent to the outer peripheral surface of the bent part 46 in the separation region D as illustrated in FIG. 6. However, in portions other than the separation region D, the inner wall of the main chamber body 12 includes a cutout having a rectangular shape in a vertical cross section, from the portion opposing the outer end surface of the turntable 2 towards the bottom surface portion 14, as illustrated in FIG. 1. A region at this cutout portion that communicates to the first process region 91 is referred to as a first exhaust region E1, and a region at this cutout portion that communicates to the second process region 92 is referred to as a second exhaust region E2. As illustrated in FIG. 3, the first and second exhaust ports 61 and 62 are respectively formed at the bottom portions of the first and second exhaust regions E1 and E2. As illustrated in FIG. 1, the first and second exhaust ports 61 and 62 are connected to a vacuum pump 64 that forms a vacuum exhaust means (or vacuum exhaust unit), through an exhaust pipe 63. In FIG. 1, a pressure adjuster 65 that forms a pressure adjusting means is provided with respect to each exhaust pipe 63.

In order to achieve the separating function of the separation region D, the first and second exhaust ports 61 and 62 are provided on respective sides of the separation region D along the rotating direction R when viewed in the plan view. More particularly, when viewed from the rotation center of the turntable 2, the first exhaust port 61 is formed between the first process region 91 and the adjacent separation region D that is on the downstream side along the rotating direction R, and the second exhaust port 62 is formed between the second process region 92 and the adjacent separation region D that is on the downstream side along the rotating direction R. The first and second exhaust ports 61 and 62 are provided exclusively (or separately) for exhausting the respective reaction gases (TiCl₄ gas and NH₃ gas). In this example, the first exhaust port 61 is provided between the first reaction gas nozzle 31 and an extension of the edge of the separation region D that is located on the side of the first reaction gas nozzle 31 adjacent to the downstream side with respect to the first reaction gas nozzle 31 along the rotating direction R. On the other hand, the second exhaust port 62 is provided between the second reaction gas nozzle 32 and an extension of the edge of the separation region D that is located on the side of the second reaction gas nozzle 32 adjacent to the downstream side with respect to the second reaction gas nozzle 32 along the rotating direction R. In other words, the first exhaust port 61 is provided between a straight line L1 indicated by a one-dot chain line in FIG. 3 passing through the center of the turntable 2 and the first process region 91, and a straight line L2 indicated by a one-dot chain line in FIG. 3 passing through the center of the turntable 2 and the upstream side edge of the separation region D adjacent to the downstream side of the first process region 91. In addition, the second exhaust port 62 is provided between a straight line L3 indicated by a two-dot chain line in FIG. 3 passing through the center of the turntable 2 and the second process region 92, and a straight line L4 indicated by a two-dot chain line in FIG. 3 passing through the center of the turntable 2 and the upstream side edge of the separation region D adjacent to the downstream side of the second process region 92.

In this example, the first and second exhaust ports 61 and 62 are provided at a position lower than the turntable 2 in order to exhaust the gas from the gap between the inner peripheral surface of the vacuum chamber 1 and the circumferential edge of the turntable 2. However, the location of the first and second exhaust ports 61 and 62 is not limited to the bottom surface portion 14 of the vacuum chamber 1, and the first and second exhaust ports 61 and 62 may be provided on the sidewall of the vacuum chamber 1.

As illustrated in FIG. 1, a heater unit 7, forming a heating means (or a heating device), is arranged in a space between the turntable 2 and the bottom surface portion 14 of the vacuum chamber 1, in order to heat the wafer W on the turntable 2 to a temperature determined by a process recipe via the turntable 2. A cover member 71 is provided to surround the entire circumference of the heater unit 7 under the vicinity of the circumferential edge of the turntable 2, in order to partition the environment from the space above the turntable 2 to the exhaust region E from the environment in which the heater unit 7 is arranged. The cover member 71 has an upper edge that is bent outwards to form a flange shape, and a gap between an upper surface of the bent upper edge of the cover member 71 and the lower surface of the turntable 2 is set narrow in order to suppress the intrusion of gas from the outside into the space surrounded by and inside the cover member 71.

The bottom surface portion 14 in the vicinity of the central part of the lower surface of the turntable 2 forms a narrow space or gap with the core part 21 in a portion closer to the rotation center than the space where the heater unit 7 is arranged. In a penetration hole penetrating the bottom surface portion 14 to accommodate the rotary shaft 22, a space or gap between the inner surface defining the penetration hole and the rotary shaft 22 is narrow in the vicinity of a central part of the lower surface of the turntable 2. These narrow spaces or gaps communicate to the inside of the case body 20. A purge gas pipe 72 for supplying the N₂ gas, forming the purge gas, into the narrow spaces or gaps to purge the narrow spaces or gaps is provided on the case body 20. In addition, a purge gas supply pipe 73 for purging the space in which the heater unit 7 is arranged is provided at a plurality of positions on the bottom surface portion 14 of the vacuum chamber 1 under the heater unit 7 along the circumferential direction.

By providing the purge gas supply pipes 72 and 73, the space from the inside of the case body 20 to the space in which the heater unit 7 is arranged may be purged by the N₂ gas, and the purge gas from the gap between the turntable 2 and the cover member 71 and through the exhaust region E may be exhausted through the first and second exhaust ports 61 and 62. Accordingly, the TiCl₄ gas or the NH₃ gas is prevented from entering from one to the other of the first and second process regions 91 and 92 through the space under the turntable 2, and the purge gas also function as a separation gas.

A separation gas supply pipe 51 is connected to a central part of the top plate 11 of the vacuum chamber 1, in order to supply the N₂ gas, forming the separation gas, into a space 52 between the top plate 11 and the core part 21. The separation gas supplied to the space 52 is ejected towards the circumferential edge of the turntable 2 along the surface thereof on the side of the substrate placing region, through a narrow gap 50 between the projecting part 5 and the turntable 2. Because the separation gas fills the space surrounded by the projecting part 5, the reaction gases (TiCl₄ gas and NH₃ gas) may be prevented from mixing between the first process region 91 and the second process region 52 through the central part of the turntable 2.

Furthermore, as illustrated in FIGS. 2 and 3, the transport port 15 for transporting the wafer W between an external transport arm 10 and the turntable 2 is provided in the sidewall of the vacuum chamber 1. This transport port 15 may be opened and closed by a gate valve (not illustrated). Because the transfer of the wafer W is performed between the external transport arm 10 at the position of the transport port 15 and the recess 24 forming the substrate placing region of the turntable 2, an elevator mechanism (not illustrated) for lifting elevation pins 16 is provided at a position corresponding to a transfer position under the turntable 2. The elevation pins 16 penetrate the recess 24 to lift the wafer W from the bottom surface of the wafer W.

The film deposition apparatus includes a control unit 100, that may be formed by a computer, and is configured to control the entire operation of the film deposition apparatus. The control unit 100 may include a processor 100A, such as a CPU (Central Processing Unit), and a storage part 100B, such as a memory. The storage part 100B may store process programs to be executed by the CPU, and various data including the recipe. The storage part 100B may also form a work memory that is used by the CPU when the CPU performs computations of the process programs. Of course, the work memory may be formed by a memory that is separate from the storage part 100B. The recipe (that is, process conditions, process parameters, etc.) stored in the storage part 100B may include the heating temperature of the wafer W, the flow rate of each reaction gas, the process pressure within the vacuum chamber 1, the rotational speed of the turntable 2, and the like with respect to each type of process performed with respect to the wafer W. When performing a film deposition process to deposit a thin film by supplying the reaction gas with respect to the wafer W, the rotational speed of the turntable 2 is set to 100 rpm to 240 rpm, for example, based on the recipe stored in the storage part 100B, in order to quickly form the thin film and to obtain a satisfactory surface morphology (that is, smoothen the surface state) of the thin film as will be described later in conjunction with example embodiments. The process programs may be installed to the storage part 100B within the control unit 100 from a tangible (or non-transitory) computer-readable storage medium 85, such as a hard disk, compact disk, magneto-optical disk, memory card, flexible disk, and semiconductor memory devices. Of course, the storage part 100B itself within the control unit 100 may form the computer-readable storage medium that stores at least one process program.

An input device (not illustrated), such as an operation panel from which an operator may input data and instructions, a display device (not illustrated) to display messages, operation menus, and states of the film deposition apparatus with respect to the operator, and the like may be connected to the control unit 100. The input device and the display device may be integrally formed in a user interface part, such as a touch-screen panel.

In response to an instruction or the like from the user interface part, arbitrary recipe and process program are read from the storage part 100B and the process program is executed by the CPU (processor 100A) under the control of the control unit 100, in order to realize a desired function of the film deposition apparatus by executing out a desired process. In other words, the process program causes the computer to realize the functions of the film deposition apparatus related to the film deposition process or, causes the computer to execute the procedures of the film deposition apparatus related to the film deposition process or, causes the computer to function as the means for executing the film deposition process of the film deposition apparatus, by controlling the film deposition apparatus. At least the process program may be installed into the control unit 100 from a tangible (or non-transitory) computer-readable storage medium that stores the process program or, the process program may be used on-line by successively transmitting the process program to the control unit 100 from an external apparatus (not illustrated) via a dedicated line, for example.

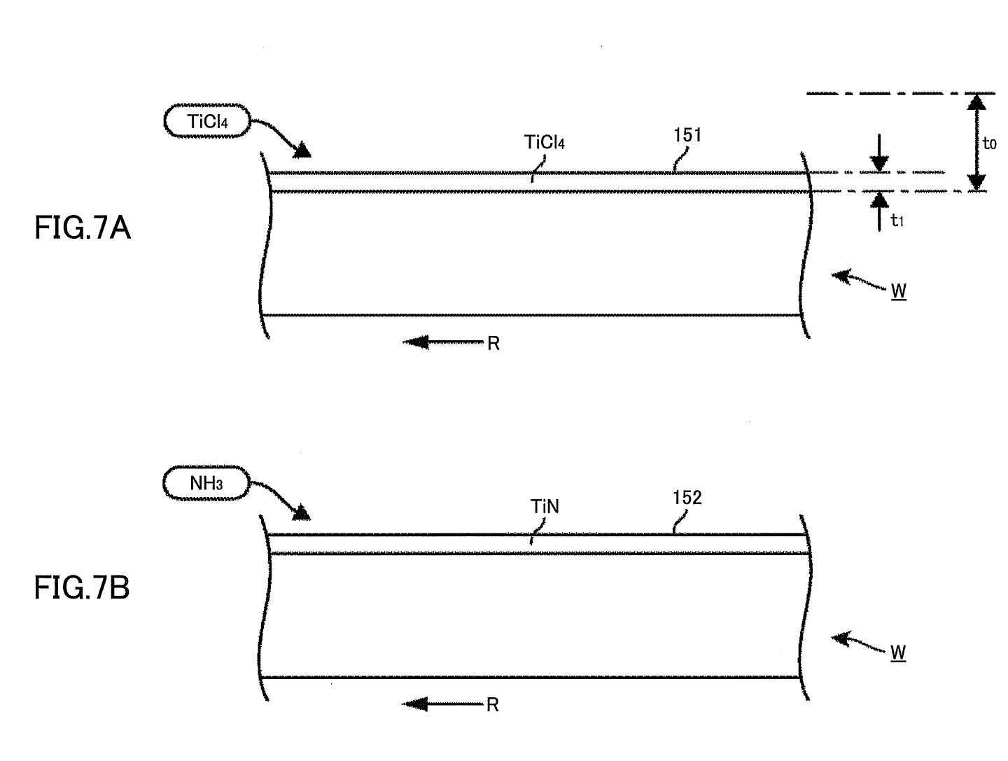

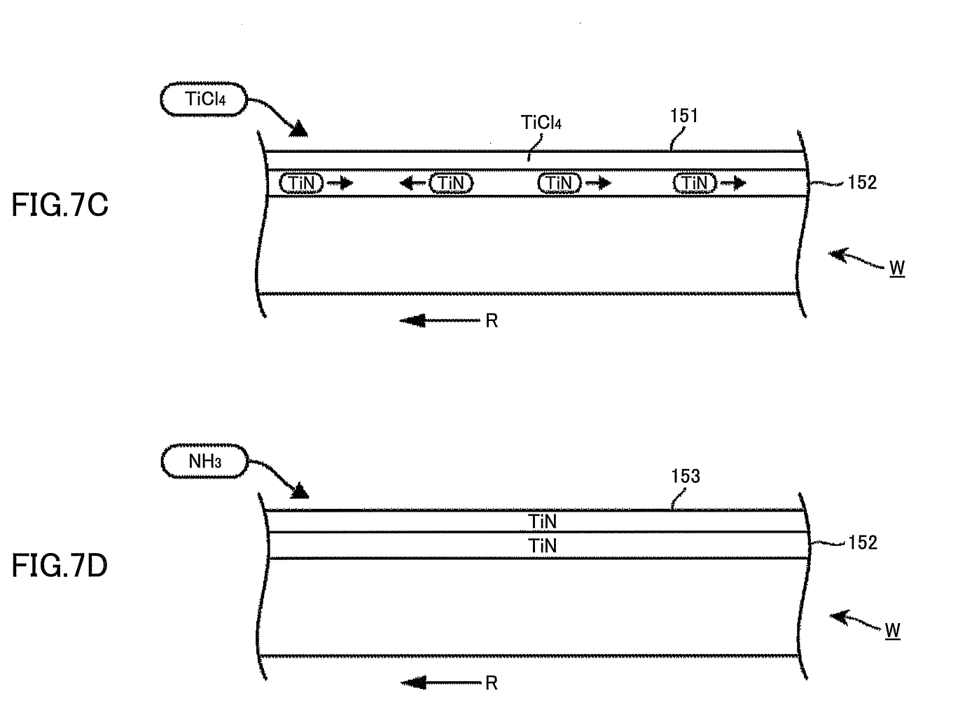

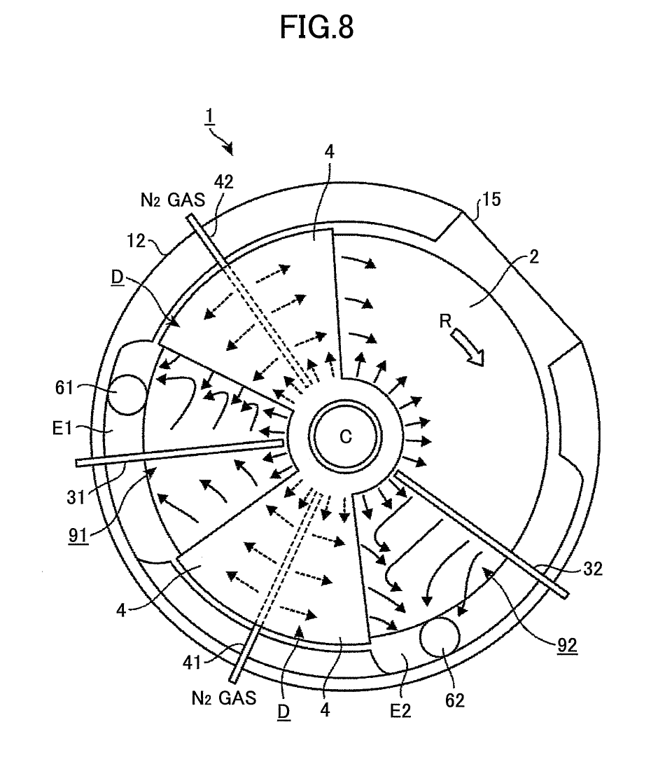

Next, a description will be given of the operation of the film deposition apparatus in the first embodiment, by referring to FIGS. 7A through 7D and 8. First, the gate valve is opened, and the wafer W is transported from the outside by the transport arm 10 onto the turntable 2 via the transport port 15, in order to place the wafer W within the recess 24 of turntable 2. When the recess 24 stops at the position corresponding to the transport port 15, the elevation pins 16 are raised from the bottom surface portion 14 of the vacuum chamber 1 through the penetration holes in the bottom surface of the recess 24. Hence, the wafer W transported by the transport arm 10 is received by the elevation pins 16, and the elevation pins 16 are thereafter lowered so that the wafer W is received by the recess 24. Such a process of receiving the wafer W by the recess 24 is performed while intermittently rotating the turntable, and as a result, the wafer W is received in each of the five recesses 24 of the turntable 2. Then, the gate valve is closed, and the pressure adjuster 65 is fully opened (100% gate opening) to decompress the vacuum chamber 1. In addition, the turntable 2 is rotated clockwise at a rotational speed of 100 rpm, for example, and the wafer W (that is, the turntable 2) is heated by the heater unit 7 to a temperature of 250° C. or higher such that the crystallization of TiN (titanium nitride) occurs. In this example, the wafer W is heated to 400° C., for example.

Next, the gate opening of the pressure adjuster 65 is adjusted so that the pressure value within the vacuum chamber 1 becomes a predetermined value, which is 1066.4 Pa (or 8 Torr), for example. In addition, the TiCl₄ gas is supplied at 100 sccm, for example, from the first reaction gas nozzle 31, and the NH₃ gas is supplied at 5000 sccm, for example, from the second reaction gas nozzle 32. Furthermore, the N₂ gas is supplied at 10000 sccm, for example, from each of the separation gas nozzles 41 and 42. Moreover, the N₂ gas is also supplied from the separation gas supply pipe 51 and the purge gas supply pipes 72 and 73 at a predetermined flow rate into the vacuum chamber 1.

When the turntable 2 rotates and the wafer W passes the first process region 91, the TiCl₄ gas is adsorbed on the surface of this wafer W as illustrated in FIG. 7A. In this state, because the turntable 2 is rotated at a high speed and the flow rate of the reaction gases and the process pressure are set as described above, a thickness t1 of a TiCl₄ gas adsorption film 151 on the wafer W becomes thinner than a saturated thickness t0 that is obtained when the wafer W is stationary within the TiCl₄ gas environment until the amount of TiCl₄ gas adsorption saturates. In order to form the TiCl₄ gas adsorption film 151 to the thickness t1 that is thinner than the saturated thickness t0, the first reaction gas nozzle 31 is provided adjacent to the wafer W and parallel to the turntable 2 from the rotation center towards the outer periphery of the turntable 2, and the ejection holes 33 are provided at constant intervals along the longitudinal direction of the first reaction gas nozzle 31. Moreover, the separation region D is provided between each adjacent process regions 91 and 92 in order to stabilize the gas flow within the vacuum chamber 1. Hence, the TiCl₄ gas is uniformly supplied onto the wafer W, and the thickness of the TiCl₄ gas adsorption film 151 becomes uniform throughout the entire top surface of the wafer W.

Next, when this wafer W passes the second process region 92, one or a plurality of molecular layers of a TiN film 152 is generated by the nitriding of the TiCl₄ gas adsorption film 151 on the top surface of the wafer W, as illustrated in FIG. 7B. The grain size of this TiN film 152 tends to become larger, that is, tends to grow, due to the migration of the atoms or molecules caused by the crystallization. As the grain growth progresses, the surface morphology of the TiN film 152 deteriorates, that is, the surface state becomes rough. However, because the turntable 2 is rotated at the high speed as described above, the wafer W having the TiN film 152 formed on the top surface thereof immediately passes the first process region 91 and quickly reaches the second process region 92. In other words, the time between cycles of the process including the adsorption of the TiCl₄ gas on the top surface of the wafer W and the nitriding of the TiCl₄ gas (that is, the time in which the crystallization of the TiN film 152 progresses) is set extremely short. For this reason, an upper TiN film 153 is deposited before the crystallization of the lower TiN film 152 progresses, as illustrated in FIGS. 7C and 7D, and the migration of the atoms and molecules in the lower TiN film 152 is suppressed by the upper TiN film 153 that is the reaction product, such that the surface state (more particularly, the grain growth) of the lower TiN film 152 is essentially restricted by the upper TiN film 153. In addition, because the thickness t1 of the TiCl₄ gas adsorption film 151 is thin as described above, the grain size that is grown (that is, the extent of deterioration of the surface morphology) may be minimized even if the crystallization of the TiN grains occurs in the lower TiN film 152. Accordingly, as will be described later in conjunction with the example embodiments, the lower TiN film 152 has an extremely small grain size and a smooth surface state, when compared to a TiN film that is formed by the CVD (Chemical Vapor Deposition) or the conventional ALD (Atomic Layer Deposition) having a long cycle time.

On the other hand, because the wafer W thereafter quickly passes the first and second process regions 91 and 92, the migration of the atoms and molecules in the upper TiN film 153 is restricted by a further upper TiN film that is deposited before the crystallization of the upper TiN film 153 progresses. Therefore, as the wafer W alternately passes the first process region 91 and the second process region 91 in this order a plurality of times, the reaction product having the extremely small grain size and the smooth surface is successively deposited to form a thin film of TiN. This thin film of TiN (or TiN thin film) may be deposited more quickly than the conventional ALD, for example, because the turntable 2 is rotated at the high speed described above. The deposition rate of this TiN thin film depends on the amount of each reaction gas supplied, the process pressure within the vacuum chamber 1, and the like, but according to one example, the deposition rate may be 5.47 nm/min.

In this state, the N₂ gas is supplied in the separation region D, and the N₂ gas forming the separation gas is also supplied in a central region C illustrated in FIGS. 1 and 3. Hence, even when the turntable 2 rotates at the high speed as described above, the gases are exhausted so that the TiCl₄ gas and the NH₃ gas do not mix, as illustrated in FIG. 8 by the arrows indicating the gas flow. In addition, in the separation region D, the gap between the bent part 46 and the outer end surface of the turntable 2 is narrow as described above, and thus, the TiCl₄ gas and the NH₃ gas do not mix even through the outer periphery of the turntable 2. Accordingly, the environment of the first process region 91 and the environment of the second process region 92 are completely separated, and the TiCl₄ gas is exhausted through the exhaust port 61 and the NH₃ gas is exhausted through the exhaust port 62. As a result, the TiCl₄ gas and the NH₃ gas will not mix within the environments nor on the wafer W. Furthermore, because the region under the turntable 2 is purged by the N₂ gas, the gas entering the exhaust region E is prevented from passing through the region under the turntable 2 and causing the TiCl₄ gas, for example, to flow into the region supplied with the NH₃ gas. When the film deposition process ends, the supply of gases is stopped and the vacuum chamber 1 is exhausted to a vacuum, and the rotation of the turntable 2 is thereafter stopped. Each wafer W may then be transported outside the vacuum chamber 1 by the transport arm 10 by carrying out an operation in a reverse sequence to that of the operation carried out when transporting the wafer W into the vacuum chamber 1.

Next, a description will be given of examples of the process parameters. The flow rate of the N₂ gas from the separation gas supply pipe 51 at the central portion of the vacuum chamber 1 is 5000 sccm, for example. In addition, the number of reaction gas supply cycles with respect to one wafer W, that is, the number of times the wafer W passes each of the first and second process regions 91 and 92, vary depending on the target film thickness, but may be a multiple value, such as 600 times, for example.

According to this embodiment, when the wafer W is placed on the turntable 2 within the vacuum chamber 1 and the reaction gases are supplied to the wafer W under the vacuum environment in order to deposit a titanium nitride film on the wafer W, the turntable 2 and each of the gas nozzles 31, 32, 41, and 42 are rotated relative to each other in the circumferential direction of the vacuum chamber 1 at a rotational speed of 100 rpm or higher during the film deposition process. For this reason, the reaction gas supply cycle (or the deposition cycle of the reaction product) is performed at a high speed, and the thin film may be formed quickly to thereby improve the throughput. In addition, because the time between the reaction gas supply cycles is extremely short, the film of the next reaction product may be deposited on the upper layer before the crystallization of the reaction product deposited on the top surface of the substrate (that is, the wafer W) progresses and before the grain diameter becomes large. In other words, the reaction product forming the upper film restricts the migration of the atoms and molecules in the reaction product of the lower film, and as a result, the migration that deteriorates the surface morphology (or surface state) may be suppressed. Hence, compared to the thin films formed by the conventional CVD or the ALD having a long time between the cycles, the thin film formed by this embodiment has a smooth surface morphology (or smooth surface state).

Therefore, if the TiN film in this embodiment is used as a barrier film for ZrO (zirconium oxide), TiO (titanium oxide), and TaO (tantalum oxide) when forming the next-generation capacitor electrode, for example, the charge concentration on the capacitor electrode may be suppressed and a satisfactory electrical characteristic may be obtained. In addition, in a semiconductor device having a multi-level interconnection structure, a contact structure uses a contact hole that is formed in an interlayer insulator to connect an interconnection layer in a lower level to an interconnection layer in an upper level, and aluminum may be used for the metal material embedded within the contact hole. If a barrier film is formed on the inner wall surface of this contact hole in order to prevent diffusion of the metal material such as aluminum into the interlayer insulator, and this barrier film is made of a TiN film of this embodiment, for example, a thin film of TiN may be deposited quickly to have a smooth surface and a sufficiently high coverage, even if the aspect ratio of the contact hole is approximately 50 and large. On the other hand, because the thickness t1 of the TiCl₄ gas adsorption film 151 on the wafer W is thinner than the saturated thickness t0, the TiN grain size that grows may be suppressed to an extremely small size even if the crystallization of the TiN grains occurs. In other words, because this embodiment rotates the turntable 2 at the high speed, the thickness t1 of the TiCl₄ gas adsorption film 151 may be controlled to be thin (that is, the grain size may be controlled to be small).

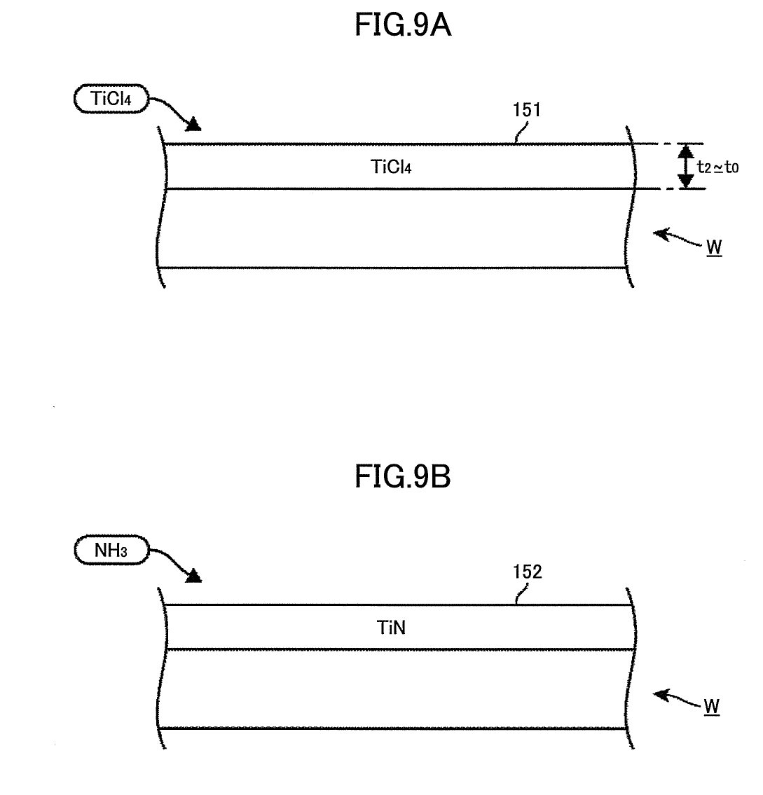

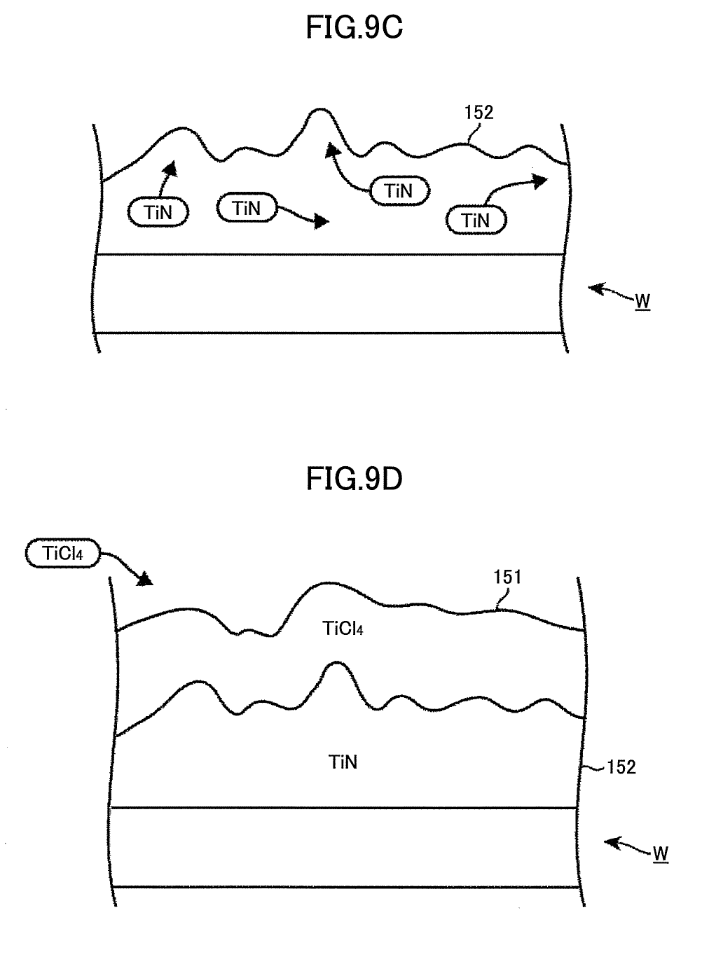

If the rotational speed of the turntable 2 were set low to 30 rpm or lower, for example, and the deposition process for the TiN film 152 is performed, a thickness t2 of the TiCl₄ gas adsorption film 151 becomes approximately equal to the saturated thickness t0 as illustrated in FIG. 9A, and the surface morphology of the thin film deteriorates. In other words, when the NH₃ gas is supplied to the wafer W having the TiCl₄ gas adsorption film 151 formed thereon in order to deposit the TiN film 152 as illustrated in FIG. 9B, the time between the process cycles of forming the TiCl₄ gas adsorption film 151 and nitriding this TiCl₄ gas adsorption film 151 becomes long. As a result, until the next TiN film 153 is deposited on the TIN film 152, the crystallization of the TiN grains progresses in the TiN film 152 as illustrated in FIG. 9C, and the migration of the atoms and molecules in the TiN film 152 occurs to deteriorate the surface morphology. In this state, the thickness t2 of the TiCl₄ gas adsorption film 151 is thicker than the thickness t1 described above, and the grain size that grows with the crystallization (or the deterioration of the surface state) may increase depending on the thickness t2.

For this reason, when the TiCl₄ gas is supplied to the surface of the TiN film 152 having the rough surface state, the upper TiCl₄ gas adsorption film 151 is formed on and follows the rough surface state of the TIN film 152, and the surface state of the upper TiCl₄ gas adsorption film 151 also becomes rough as illustrated in FIG. 9D. Thereafter, when the NH₃ gas is supplied on the upper TiCl₄ gas adsorption film 151, the crystallization similarly progresses in the upper TiN film 153, to thereby further deteriorate the rough surface state. When the crystallization progresses in each of the successively deposited TiN films, the surface state of the thin film that is finally formed becomes extremely rough. Accordingly, when the film deposition process is performed by setting the rotational speed of the turntable 2 to such a low speed, it may be extremely difficult to control the surface morphology. Furthermore, when the rotational speed of the turntable 2 is low, the film deposition rate becomes slow.

Therefore, this embodiment sets the rotational speed of the turntable 2 to a high speed when depositing the TiN film, in order to quickly form the TIN film having the satisfactory surface morphology. In the film deposition apparatus of this embodiment, the first and second reaction gas nozzles 31 and 32 are provided to oppose the wafer W on the turntable 2, and thus, the flow rate of the reaction gases may be set high or, the process pressure may be set high, so that the amount of reaction gas adsorbed on the wafer W saturates. In this case, because the turntable 2 is rotated at the high speed, the upper TiN film 153 may be deposited before the crystallization of the TiN film 152 progresses, and a satisfactory surface morphology may be achieved. In addition, since the film thickness may be increased in each reaction cycle, the throughput may further be improved. Of course, the reaction gases are exhausted separately also when the amount of reaction gases supplied is increased or the process pressure is increased.

The first reaction gas may be a gas other than that described above and including Ti, such as TDMAT (Tetrakis-Di-Methyl-Amino-Titanium), for example. In addition, the second reaction gas may be a radical of the NH₃ gas. Moreover, because the coverage of the thin film may deteriorate if the rotational speed of the turntable 2 is too high, the rotational speed may be set to 240 rpm or lower, for example. In other words, when experiments were conducted for the deposition of the TiN film in the example embodiments which will be described later, a satisfactory coverage was achieved when the turntable 2 was rotated at 240 rpm, and thus, it may be regarded that the satisfactory coverage is obtainable when the rotational speed of the turntable 2 is at least 240 rpm.

### Second Embodiment

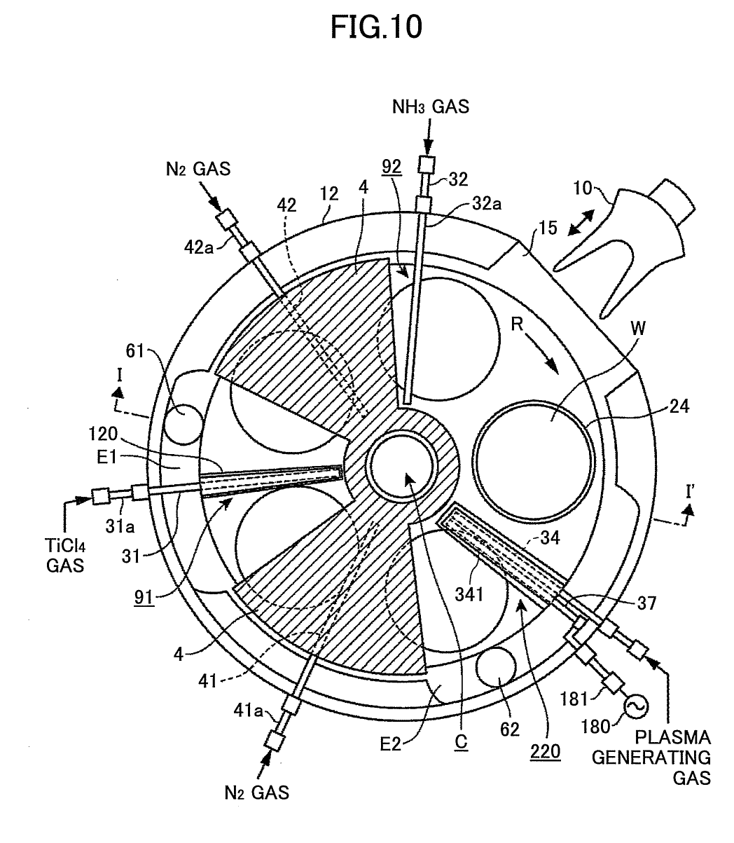

In the first embodiment described above, the film deposition cycle including the formation of the TiCl₄ gas adsorption film 151 and the formation of the TiN film 152 by the nitriding of the TiCl₄ gas adsorption film 151 is repeated a plurality of times to deposit the thin film. However, if impurities are included in the TiN film 152, for example, a plasma process may be performed with respect to the TiN film 152 between the film deposition cycles. Next, a description will be given of an example of the film deposition apparatus of a second embodiment of the present invention, that may perform such a plasma process, by referring to FIGS. 10 through 12. In FIGS. 10 through 12, those parts that are the same as those corresponding parts in FIGS. 1 through 6 are designated by the same reference numerals, and a description thereof will be omitted.

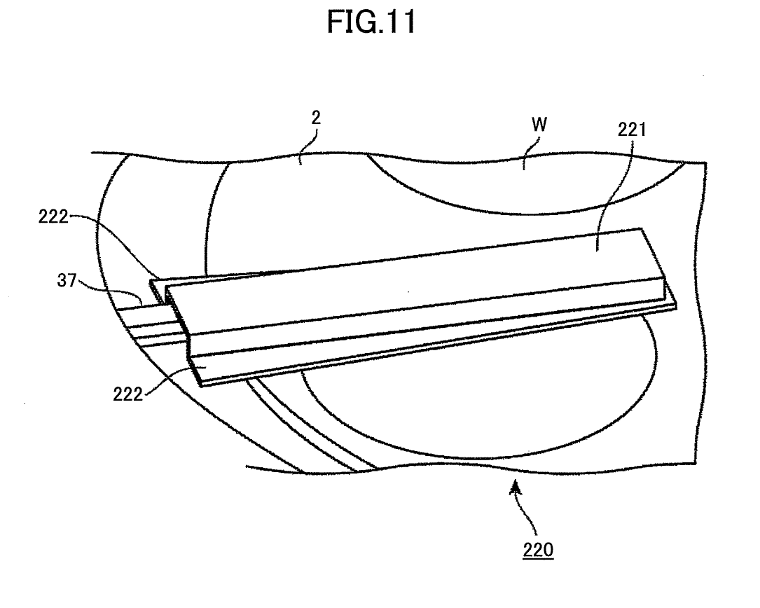

In this example, the second reaction gas nozzle 32 is provided on the upstream side of the transport port 15 along the rotating direction R of the turntable 2 in FIG. 10. In addition, an activation gas injector 220 for carrying out the plasma process with respect to the wafer W is provided between the second reaction gas nozzle 32 and the separation region D that is located on the downstream side of this second reaction gas nozzle 32 along the rotating direction R of the turntable 2. The activation gas injector 220 includes a gas introducing nozzle 34 that extends parallel to the turntable 2 from the outer periphery towards the rotation center of the turntable 2, a pair of sheath pipes (not illustrated), and a cover body 221 having a structure similar to that of the nozzle cover 120 described above. The cover body 221 is made of quartz, for example, and covers a region in which the gas introducing nozzle 34 and the pair of sheath pipes are arranged from above this region. A current restricting surface 222 illustrated in FIG. 11 has a dimension similar to that of the flange-shaped flow regulatory plate (or diffuser) 121 described above. A support 223 illustrated in FIG. 12 is provided along the longitudinal direction of the cover body 221 in order to hang the cover body 221 from the top plate 11 of the vacuum chamber 1. A protection pipe 37 illustrated in FIG. 10 connects to the base ends of the sheath pipes (that is, the inner wall of the vacuum chamber 1).

A high-frequency power supply 180 illustrated in FIG. 10 is provided outside the vacuum chamber 1, and high-frequency power of 1500 W or less at 13.56 MHz, for example, may be supplied to electrodes (not illustrated) embedded with the sheath pipes via a matching box 181. The gas introducing nozzle 34 includes gas holes 341 formed on a side at a plurality of positions along the longitudinal direction thereof. A process gas for generating plasma, that is, at least one of NH₃ gas and H₂ gas, supplied from the outside of the vacuum chamber 1, is ejected horizontally towards the sheath pipes via the gas holes 341.

When performing the film deposition process in this second embodiment, the gas is supplied into the vacuum chamber 1 from each of the gas nozzles 31, 32, 41, and 42. In addition, the process gas for generating plasma is supplied from the gas introducing nozzle 34 at a predetermined flow rate. For example, the NH₃ gas is supplied at 5000 sccm from the gas introducing nozzle 34 into the vacuum chamber 1. Another high-frequency power supply (not illustrated) supplies a predetermined high-frequency power of 400 W, for example, with respect to the electrodes described above.

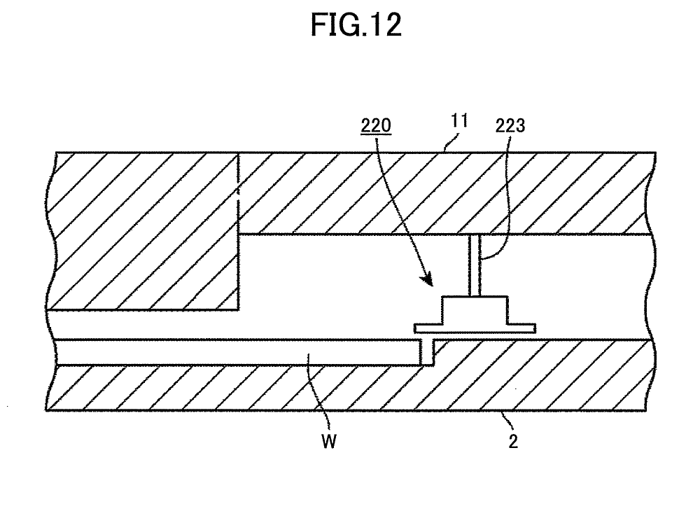

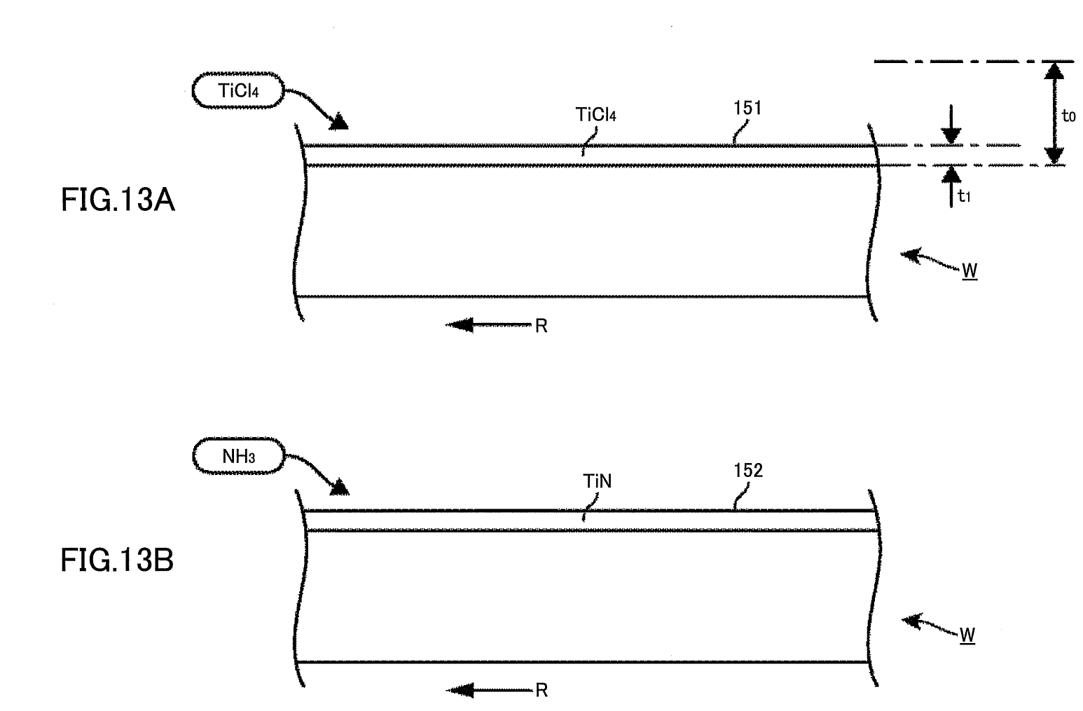

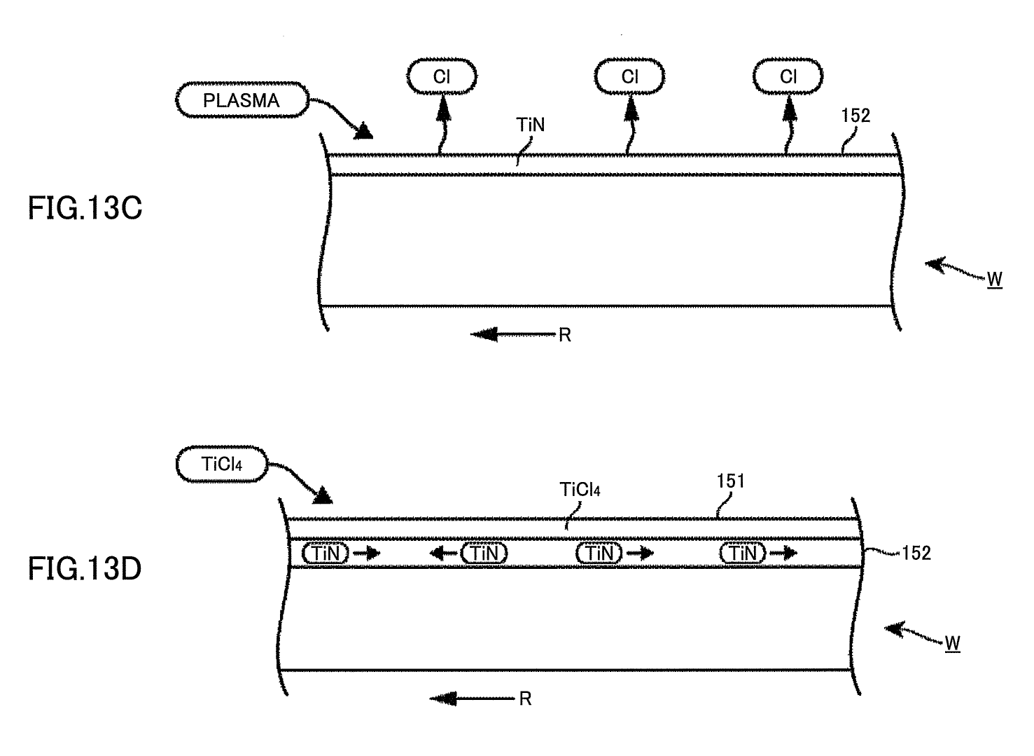

In the activation gas injector 220, the NH₃ gas ejected from the gas introducing nozzle 34 towards the sheath pipes are activated by the high-frequency power supplied between the sheath pipes to generate an active form such as ions, and the active form (or plasma) is ejected downwards towards the turntable 2. As illustrated in FIGS. 13A and 13B, a TiCl₄ gas adsorption film 151 is formed on the top surface of the wafer W, and a TiN film 152 is formed by nitriding the TiCl₄ gas adsorption film 151. When the wafer W having the TiN film 152 formed thereon reaches a region under the activation gas injector 220 and is subjected to plasma bombardment, an impurity such as Cl (chlorine) included in the TiN film 152 at the surface is ejected out of the TiN film 152 as illustrated in FIG. 13C. Then, a next TiN film 153 is quickly deposited on the lower TiN film 152 to restrict the migration of the atoms and molecules in the lower TiN film 152 as illustrated in FIG. 13D, in a manner similar to that of the first embodiment described above. Hence, by repeating the deposition of the TiCl₄ gas adsorption film 151, the generation of the TiN film 152 by nitriding the TiCl₄ gas adsorption film 151, and the reduction (or elimination) of the impurities in the TiN film 152 by the plasma process a plurality of times in this order, a thin film having an extremely low impurity concentration and a smooth surface may be formed quickly.

According to this second embodiment, it may be possible to obtained the following effects in addition to the effects obtainable in the first embodiment described above. That is, by performing the plasma process with respect to the wafer W, the amount of impurities within the thin film may be reduced, to thereby improve the electrical characteristics. In addition, because a reforming process is performed every time the film deposition cycle is performed within the vacuum chamber 1, the reforming process is performed so as not to interfere with the film deposition process at an intermediate stage when the wafer W moves in a path passing the first and second process regions 91 and 92 along the circumferential direction of the turntable 2. Thus, the reforming process may be performed within a short time when compared to a case where the reforming process is performed separately after the film deposition process is completed, for example.

In the examples described above, the turntable 2 is rotated with respect to the gas supply system (that is, the nozzles 31, 32, 41, and 42). However, it is of course possible to rotate the gas supply system with respect to the turntable 2.

Next, a description will be given of the experiments conducted in order to confirm the effects of the film deposition apparatus and the film deposition method according to the above described embodiments.

### Example Embodiment 1

First, a TiN film was deposited by varying the rotational speed of the turntable 2 in the following manner, and the surface of the deposited TiN film was observed using a SEM (Scanning Electron Microscope). The film deposition conditions, such as the amount of reaction gas supplied and the process pressure, were the same as those of the embodiments described above, and a description thereof will be omitted. The wafer W was heated to a heating temperature of 250° C. or higher, and to 400° C., for example.

### Rotational Speed of Turntable 2: rpm

Comparison Example 1: 30

Example Embodiment 1: 100 or 240

### Experimental Results

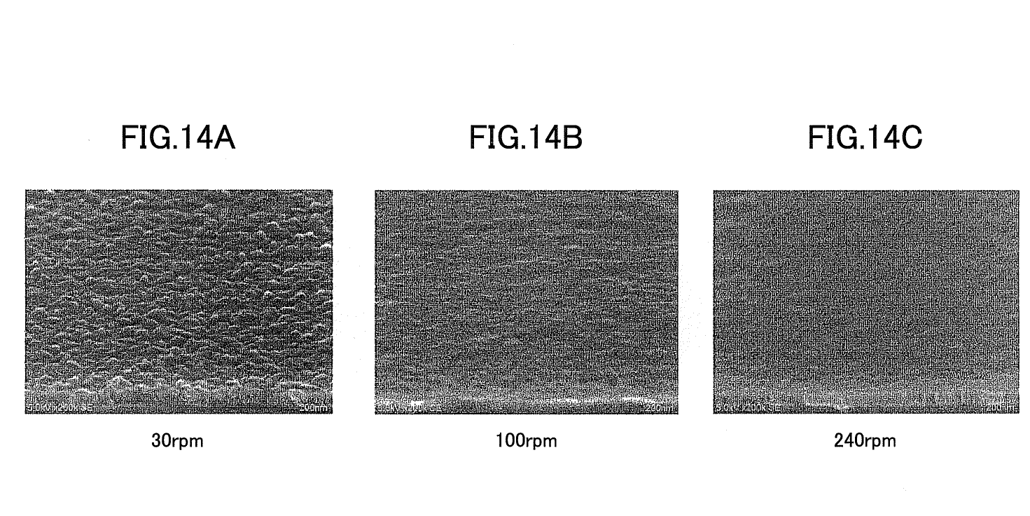

FIGS. 14A through 14C are diagrams illustrating experimental results, namely, SEM photographs. For the comparison example 1, the surface state was rough as illustrated in FIG. 14A, and it was confirmed that the surface state is similar to that obtained when depositing the film by the conventional CVD or SFD. As described above, crystallization of TiN occurs at a temperature of 250° C. or higher. Hence, it may be regarded that the surface roughness caused by the crystallization of the TiN grains is generated when the crystallization of the TiN grains cannot be prevented at the heating temperature used in the experiments.

On the other hand, for the example embodiment 1, the surface morphology of the TiN film improved as illustrated in FIG. 14B when the rotational speed of the turntable 2 was set to 100 rpm and higher than that of the comparison example 1. In addition, for the example embodiment 1, the surface morphology of the TiN film further improved and an extremely smooth surface was obtained as illustrated in FIG. 14C when the rotational speed of the turntable 2 was set to 240 rpm and higher than that of the comparison example 1. Accordingly, by rotating the turntable 2 at the high speed, the time between the film deposition cycles becomes short as described above, and it was confirmed that the crystallization of the lower TiN film under the upper TiN film may be suppressed.

### Example Embodiment 2

Next, with respect to each sample created under the same conditions as the example embodiment 1 described above, the surface roughness of the TiN film was measured using an AFM (Atomic Force Microscope). The measuring length was set to 10 nm.

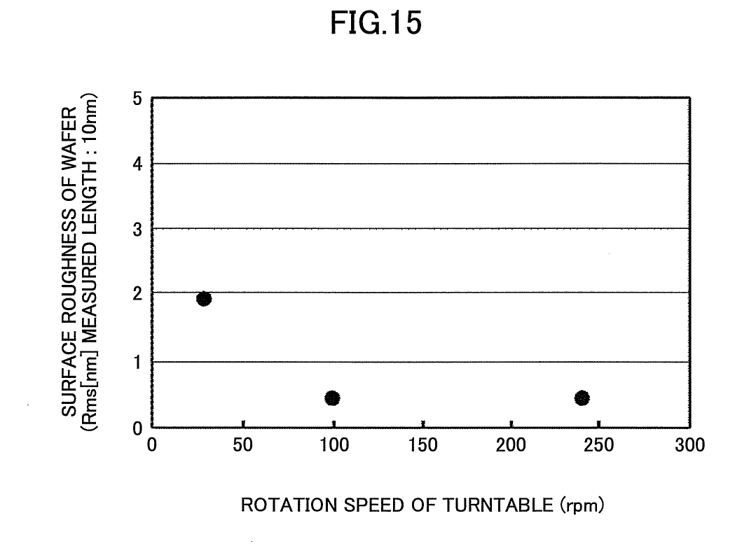

As a result, it was confirmed that the surface roughness is approximately 2 nm when the rotational speed of the turntable 2 is 30 rpm, and the surface roughness is approximately 0.5 nm and small when the rotational speed of the turntable 2 is 100 rpm or higher, as illustrated in FIG. 15.

In the examples described for the embodiments described above, the first reaction gas including Ti and the second reaction gas including N are alternately supplied within the vacuum chamber by rotating the turntable on which the processing target substrate is placed or the first and second reaction gas supply means that supply the two kinds of reaction gases, relative to each other along the circumferential direction of the vacuum chamber at a rotational speed of 100 rpm or higher, in order to form a titanium nitride film on the surface of the substrate. For this reason, the supply cycle of the two kinds of reaction gases may be performed at a high speed, to thereby quickly deposit the titanium nitride film. In addition, because the time between the reaction gas supply cycles of the two kinds of reaction gases may be extremely short, a film of the next reaction product may be deposited on a reaction product deposited on the substrate surface before the growth of the grain size progresses due to crystallization of the reaction product deposited on the substrate surface. Hence, the migration of the atoms and molecules in the lower reaction product deposited on the substrate surface may be suppressed by the upper reaction product formed on the lower reaction product. As a result, a titanium nitride film having a satisfactory surface morphology, that is, a smooth surface, may be obtained.

Further, the present invention is not limited to these embodiments, but various variations and modifications may be made without departing from the scope of the present invention.

What is claimed is:

1. A film deposition apparatus comprising;
a table, provided inside a vacuum chamber, and having a substrate placing region on which a substrate is placed;
a first reaction gas supply unit and a second reaction gas supply unit provided at separate locations along a circumferential direction of the vacuum chamber, and configured to supply a first reaction gas including titanium (Ti) and a second reaction gas including nitrogen (N) to the substrate on the table, respectively;
a separation region provided between a first process region supplied with the first reaction gas and a second process region supplied with the second reaction gas, and configured to separate the first and second reaction gases;
a rotating mechanism configured to rotate one of the table and the first and second reaction gas supply units relative to each other along the circumferential direction of the vacuum chamber so that the substrate passes the first process region and the second process region in this order;
a vacuum exhaust unit configured to exhaust the inside of the vacuum chamber to vacuum; and
a control unit configured to rotate one of the table and the first and second reaction gas supply units relative to each other via the rotating mechanism at a rotational speed of 100 rpm or higher when depositing a film on the substrate,
wherein a titanium nitride film is formed on the substrate by sequentially supplying the first reaction gas and the second reaction gas to a surface of the substrate inside the vacuum chamber.

2. The film deposition apparatus as claimed in claim 1, further comprising:
an activation gas injector configured to supply at least one of ammonia (NH₃) gas and hydrogen (H₂) gas with respect to the substrate on the table,
wherein the activation gas injector is rotated by the rotating mechanism together with one of the table and the first and second reaction gas supply units in order to rotate relative to each other, and the activation gas injector is arranged to supply the plasma to the substrate between the first process region and the second process region during the relative rotation thereof.

3. The film deposition apparatus as claimed in claim 1, further comprising:
a separation gas supply unit configured to supply a separation gas to the separation region.

4. The film deposition apparatus as claimed in claim 3, wherein the separation region is formed by the separation gas supply unit and a ceiling surface located on both sides of the separation gas supply unit along the circumferential direction, and a narrow space is formed between the ceiling surface and the table to flow the separation gas from the separation region towards one of the first and second process regions.

5. The film deposition apparatus as claimed in claim 1, wherein the first and second reaction gas supply units are respectively provided in a vicinity of the substrate but separated from a ceiling surface in the first and second process regions, and are configured to respectively supply the first and second reaction gases towards the substrate.

6. A film deposition method for sequentially supplying a first reaction gas including titanium (Ti) and a second reaction gas including nitrogen (N) to a surface of a substrate inside a vacuum chamber in order to form a titanium nitride film, comprising:
supplying the first reaction gas and the second reaction gas from a first reaction gas supply unit and a second reaction gas supply unit that are provided at separate locations along a circumferential direction of the vacuum chamber, with respect to a surface of a table that includes a substrate placing region in which the substrate is placed;
separating the first and second reaction gases in a separation region provided between a first process region supplied with the first reaction gas and a second process region supplied with the second reaction gas;
rotating one of the table and the first and second reaction gas supply units relative to each other along the circumferential direction of the vacuum chamber at a rotational speed of 100 rpm or higher so that the substrate passes the first process region and the second process region in this order; and
exhausting the inside of the vacuum chamber to vacuum.

7. The film deposition method as claimed in claim 6, further comprising:
supplying at least one of ammonia (NH₃) gas and hydrogen (H₂) gas with respect to the substrate on the table from an activation gas injector,
wherein the rotating rotates the activation gas injector together with one of the table and the first and second reaction gas supply units in order to rotate relative to each other, so that the activation gas injector supplies the plasma to the substrate between the first process region and the second process region during the relative rotation thereof.

8. The film deposition method as claimed in claim 6, wherein the separating supplies a separation gas to the separation region from a separation gas supply unit.

9. The film deposition method as claimed in claim 8, wherein the separation gas is supplied from the separation gas supply unit to a narrow space formed between the table and a ceiling surface located on both sides of the separation gas supply unit along the circumferential direction so that the separation gas flows from the separation region towards one of the first and second process regions.

10. The film deposition method as claimed in claim 6, wherein the supplying supplies the first and second reaction gases towards the substrate from the first and second reaction gas supply units that are respectively provided in a vicinity of the substrate but separated from a ceiling surface in the first and second process regions.

11. A tangible computer-readable storage medium which stores a program which, when executed by a computer, causes the computer to perform a process of a film deposition apparatus that sequentially supplies a first reaction gas including titanium (Ti) and a second reaction gas including nitrogen (N) to a surface of a substrate inside a vacuum chamber in order to form a titanium nitride film, said process comprising:
a supplying procedure causing the computer to supply the first reaction gas and the second reaction gas from a first reaction gas supply unit and a second reaction gas supply unit that are provided at separate locations along a circumferential direction of the vacuum chamber, with respect to a surface of a table that includes a substrate placing region in which the substrate is placed;
a separating procedure causing the computer to separate the first and second reaction gases in a separation region provided between a first process region supplied with the first reaction gas and a second process region supplied with the second reaction gas;
a rotating procedure causing the computer to rotate one of the table and the first and second reaction gas supply units relative to each other along the circumferential direction of the vacuum chamber at a rotational speed of 100 rpm or higher so that the substrate passes the first process region and the second process region in this order; and
an exhausting procedure causing the computer to exhaust the inside of the vacuum chamber to vacuum.

12. The tangible computer-readable storage medium as claimed in claim 11, wherein said process further comprises:
a procedure causing the computer to supply at least one of ammonia (NH₃) gas and hydrogen (H₂) gas with respect to the substrate on the table from an activation gas injector,
wherein the rotating procedure causes the computer to rotate the activation gas injector together with one of the table and the first and second reaction gas supply units in order to rotate relative to each other, so that the activation gas injector supplies the plasma to the substrate between the first process region and the second process region during the relative rotation thereof.

13. The tangible computer-readable storage medium as claimed in claim 11, wherein the separating procedure causes the computer to supply a separation gas to the separation region from a separation gas supply unit.

14. The tangible computer-readable storage medium as claimed in claim 13, wherein the separation gas is supplied from the separation gas supply unit to a narrow space formed between the table and a ceiling surface located on both sides of the separation gas supply unit along the circumferential direction so that the separation gas flows from the separation region towards one of the first and second process regions.

15. The tangible computer-readable storage medium as claimed in claim 11, wherein the supplying procedure causes the computer to supply the first and second reaction gases towards the substrate from the first and second reaction gas supply units that are respectively provided in a vicinity of the substrate but separated from a ceiling surface in the first and second process regions.
